(19) United States
(12) Patent Application Publication
(10) Pub. No.: US 2023/0096772 A1
(43) Pub. Date: Mar. 30, 2023

(54) APPARATUS AND METHODS TO REDUCE PARTICLES IN A FILM DEPOSITION CHAMBER

(71) Applicant: Applied Materials, Inc., Santa Clara, CA (US)

(72) Inventors: Maribel Maldonado-Garcia, San Jose, CA (US); Cong Trinh, Santa Clara, CA (US); Mihaela A. Balseanu, Sunnyvale, CA (US); Kevin Griffin, Livermore, CA (US); Ning Li, San Jose, CA (US); Zohreh Razavi Hesabi, Milpitas, CA (US)

(73) Assignee: Applied Materials, Inc., Santa Clara, CA (US)

(21) Appl. No.: 18/074,872

(22) Filed: Dec. 5, 2022

Related U.S. Application Data
(62) Division of application No. 16/910,825, filed on Jun. 24, 2020.

(51) Int. Cl. C23C 16/448; C23C 16/455; C23C 16/52; C23C 16/34

(52) U.S. Cl. CPC C23C 16/4486; C23C 16/45561; C23C 16/45544; C23C 16/52; C23C 16/45553; C23C 16/45563; C23C 16/345

(57) ABSTRACT

Apparatus and methods for supplying a vapor to a processing chamber such as a film deposition chamber are described. The vapor delivery apparatus comprises an inlet conduit and an outlet conduit, in fluid communication with an ampoule. A needle valve device restricts flow through the outlet conduit.

### CROSS-REFERENCE TO RELATED APPLICATIONS

This application is a divisional of U.S. patent application Ser. No. 16/910,825, filed Jun. 24, 2020, the entire disclosure of which is hereby incorporated by reference herein.

### BACKGROUND

Precursor vapor (e.g., metal-organic precursor vapor) is commonly used for film deposition processes including the thermal deposition of one or more precursor vapors in a processing chamber. Precursors such as metal-organic precursors are usually in liquid or solid form. Precursor vapor is usually generated thermally inside a closed container or ampoule. Molecules of the precursor are then delivered to a substrate surface inside the processing chamber through a gas delivery gas conduit. To prevent the vapor reverting back to its bulk form, the gas delivery conduit is usually thermally controlled to be above the dew point of the particular precursor.

An inert gas is usually used to carry the precursor vapor along the gas delivery gas conduit. The carrier gas typically increases the partial pressure of the precursor due to agitation of gas flow into the container and dilutes the precursor inside the gas, adjusting the total precursor concentration.

Vaporization of precursors and deposition of thin films in a reactive gaseous environment are sensitive to gas flow, and precisely controlled gas flows are required in methods and apparatus for delivering precursors to film deposition chambers. Variability in gas flows causes chamber to chamber variability and product variability. Flow of precursors that are thermally unstable and/or reactive with oxygen and moisture such as water vapor can be difficult to control because these precursors can form particulate contaminants in the processing chamber precursor delivery system. Therefore, there is a need for apparatus and methods to provide improved flow control of precursors delivered to processing chambers.

### SUMMARY

One or more embodiments of the disclosure are directed to an apparatus comprising an ampoule having an outside surface and an inside surface defining an ampoule interior configured to contain a fluid therein; a gas delivery system including a valve cluster connected to the outside surface of the ampoule, the valve cluster including an inlet conduit connected to the ampoule and configured to allow gas to flow into the ampoule, an outlet conduit connected to the ampoule and configured to allow gas to flow out of the ampoule, a first inlet valve connected to the inlet conduit, and a first outlet valve connected to the outlet conduit; a gas pressure sensor configured to monitor pressure of the gas in the gas delivery system; and a needle valve downstream from the ampoule, the needle valve configured to variably adjust the pressure of the gas to a predetermined gas pressure value.

Additional embodiments of the disclosure are directed to an apparatus comprising an ampoule having an outside surface and an inside surface defining an ampoule interior configured to contain a fluid therein; a gas delivery system including a valve cluster connected to the outside surface of the ampoule, the valve cluster including an inlet conduit connected to the ampoule and configured to allow gas to flow into the ampoule, an outlet conduit connected to the ampoule and configured to allow gas to flow out of the ampoule, a first inlet valve connected to the inlet conduit, and a first outlet valve connected to the outlet conduit; a precursor contained with the ampoule, the precursor susceptible to formation of particulate contamination within the gas delivery system; a gas pressure sensor configured to monitor pressure of the gas in the gas delivery system; a needle valve downstream from the ampoule, the needle valve configured to variably adjust the pressure of the gas to a predetermined gas pressure value; and a controller in communication with the gas pressure sensor and the needle valve, the controller configured to send a signal to adjust the needle valve to change the gas pressure in the gas delivery system; a gas pressure sensor configured to monitor pressure of the gas in the gas delivery system; and a needle valve downstream from the ampoule, the needle valve configured to variably adjust the pressure of the gas to a predetermined gas pressure value.

Further embodiments of the disclosure are directed to a method of controlling flow of gas in a film deposition chamber. The method comprises flowing a carrier gas through an ampoule having an interior volume containing a precursor, the carrier gas exiting the ampoule mixed with a vapor of the precursor; flowing the carrier gas mixed with the vapor of the precursor through a gas delivery system and to the film deposition chamber; measuring a pressure of the gas mixed with the vapor of the precursor in the gas delivery system; and controlling the pressure of the gas mixed with the vapor of the precursor in the gas delivery system to a predetermined gas pressure value using a needle valve in communication with a gas pressure sensor.

### BRIEF DESCRIPTION OF THE DRAWINGS

So that the manner in which the exemplary embodiments of the present invention are attained and can be understood in detail, a more particular description of the disclosure, briefly summarized above, may be had by reference to the embodiments thereof which are illustrated in the appended drawings. It is to be appreciated that certain well known processes are not discussed herein in order to not obscure the invention.

FIG. 1 shows a schematic of an apparatus in accordance with one or more embodiments of the disclosure;

FIG. 2A shows a schematic of an apparatus in accordance with one or more embodiments of the disclosure;

FIG. 2B shows a schematic of an apparatus in accordance with one or more embodiments of the disclosure;

FIG. 2C shows a schematic of an apparatus in accordance with one or more embodiments of the disclosure; and

FIG. 3 is a flowchart showing a method according to one or more embodiments.

### DETAILED DESCRIPTION

One or more embodiments of the disclosure provide apparatus and methods for providing accurate concentration control delivery of precursors to processing chambers.

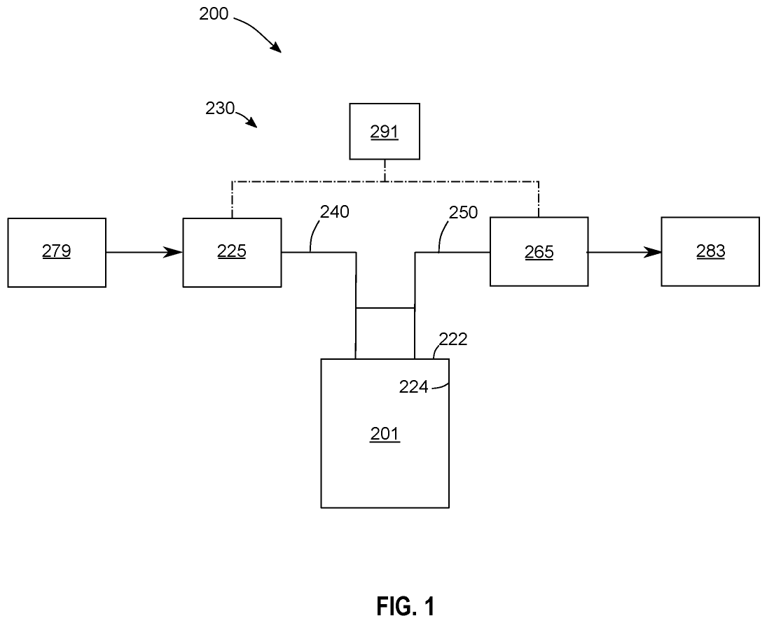

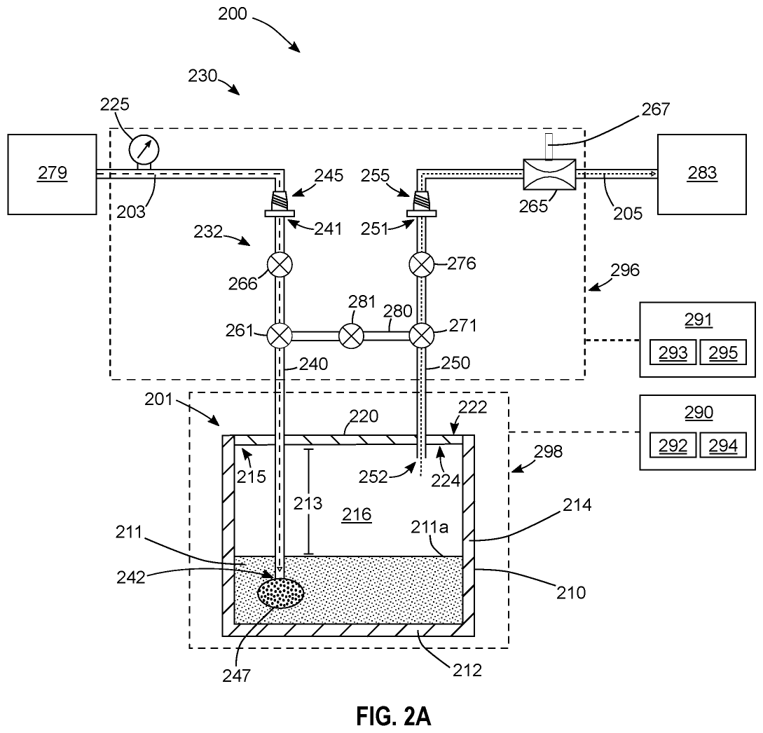

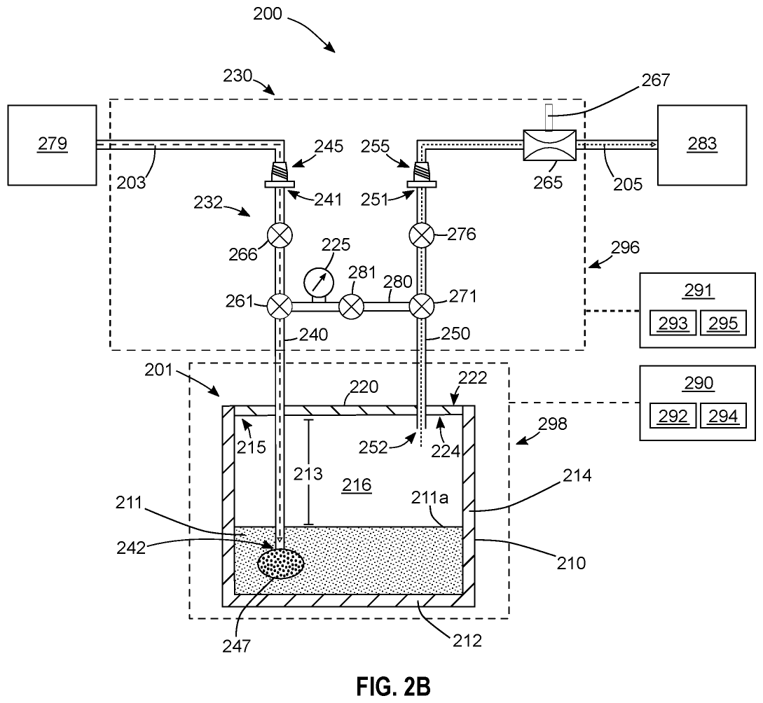

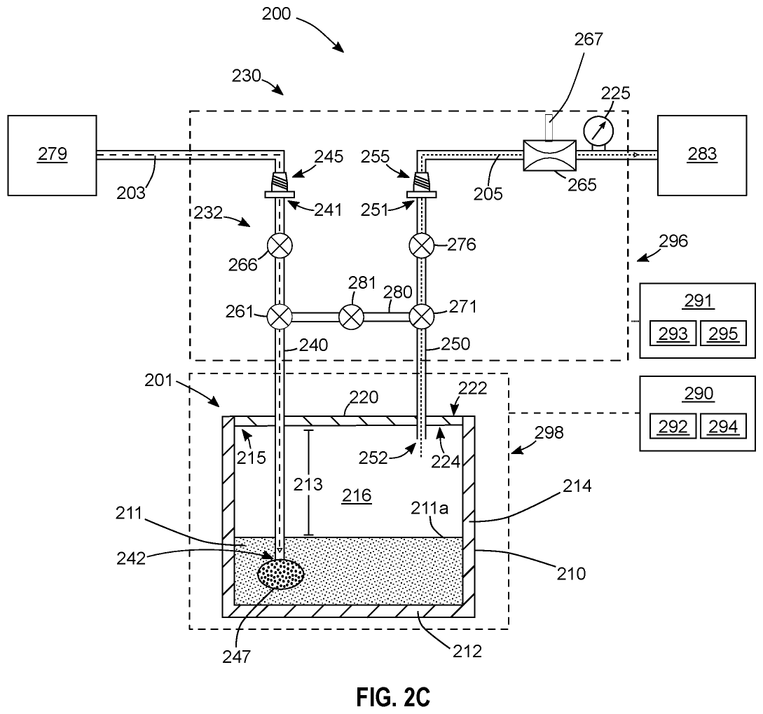

FIG. 1 shows an overview of an embodiment of the disclosure, and FIGS. 2A-C show specific embodiments. According to an embodiment of the disclosure, FIG. 1 shows an apparatus 200 including an ampoule 201 having an outside surface 222 and an inside surface 224 defining an ampoule interior configured to contain a fluid in the interior of the ampoule 201. The apparatus further includes a gas delivery system 230, which in some embodiments includes a valve cluster 232 (shown in FIGS. 2A-C) connected to the outside surface 222 of the ampoule 201, the valve cluster 232 including an inlet conduit 240 connected to the ampoule 201 and configured to allow gas to flow into the ampoule 201, an outlet conduit 250 connected to the ampoule 201 and configured to allow gas to flow out of the ampoule 201. The apparatus according to some embodiments and shown in the embodiments with respect to FIGS. 2A-C further comprises a first inlet valve 261 connected to the inlet conduit 240, and a first outlet valve 271 connected to the outlet conduit 250. The apparatus further comprises a gas pressure sensor 225 configured to monitor pressure of the gas in the gas delivery system 230. Any suitable gas pressure sensor such as a manometer or a pressure transducer suitable for use in a chemical vapor deposition or atomic layer deposition system. The apparatus further comprises a flow restrictive device in the form of a needle valve 265 downstream from the ampoule 201, 201 the needle valve 265 is configured to variably adjust the pressure of the gas to a predetermined gas pressure value. The needle valve controls gas/vapor flows to a processing chamber. Typical types of flow restrictive devices include a VCR orifice gasket flow restrictor, a porous metal flow restrictor, and needle valve. However, it was determined that only a needle valve could be utilized to reliably deliver precursors to a film formation chamber, particularly for precursors that are susceptible to formation of particulate in the gas delivery system.

In one or more embodiments, the apparatus 200 includes a first controller 291 in communication with the gas pressure sensor 225 and the needle valve 265, the controller configured to send a signal to adjust the needle valve 265 to change the gas pressure in the gas delivery system 230. In one or more embodiments, the needle valve 265 comprises a manual control including a Vernier handle 267 configured to provide fine adjustment of gas flow through the needle valve 265. A needle valve with a Vernier handle 267 in some embodiments provides fine control to allow for precise regulations of gas flow and pressure in the gas delivery system 230. The Vernier handle 267 in some embodiments may include a scale (not shown) on the handle that can be used for visual detection of movement and adjustment of the Vernier handle to allow for precise adjustment of gas pressure in the gas delivery system 230. In other embodiments, the needle valve 265 comprises a motor controlled valve. Examples of motor controlled valves comprise motor controlled actuator valves, for example, a pneumatic controlled valve, an electric controlled valve, a hydraulic controlled valve or a piezoelectric controlled linear actuator valve. In one or more embodiments, the first controller 291 controls operation of the motor controlled valve.

FIGS. 2A-C show specific embodiments of an apparatus 200 which can be used for the delivering vapor precursors to a substrate processing chamber such as a film deposition chamber according to one or more embodiments of the disclosure. The apparatus 200 shown in FIGS. 2A-C includes a closed container or ampoule 201. While the ampoule 201 shown includes an ampoule base 210, an ampoule lid 220 and a valve cluster 232, those skilled in the art will understand that the disclosure is not limited to the configuration shown. Some embodiments of the disclosure are directed to an ampoule 201 with a valve cluster 232 attached or connected to the ampoule 201. For example, in some embodiments, the valve cluster 232 can be retrofit onto an existing ampoule base 210. Some embodiments are directed to an apparatus or a method that include a valve cluster 232 that is configured to be retrofit onto an existing ampoule lid 220.

In the embodiments shown with respect to FIGS. 2A-C, the ampoule base 210 has a bottom 212 with a sidewall 214 extending from the bottom 212 defining an interior volume 216 configured to contain a liquid precursor 211 defining a liquid level surface 211a, which is the top of the liquid precursor 211 in the ampoule 201. In some embodiments, the ampoule is configured to contain a solid precursor. The bottom 212 and the sidewall 214 in some embodiments are configured to be integrally formed as a single component, or in other embodiments, are configured as multiple components joined together. In some embodiments, the ampoule base 210 is a single component formed into a cup-like shape so that the sidewall 214 and bottom 212 form the interior volume 216 of the ampoule 201, which is configured to contain the liquid precursor 211 and includes a headspace 213 above the liquid level surface 211a. It will be appreciated that the liquid level surface 211a can decrease as liquid precursor 211 is used during a manufacturing process, and the headspace 213 increases in volume as the liquid level decreases.

In the embodiments shown, the ampoule lid 220 is positioned at a top end 215 of the sidewall 214 of the ampoule base 210. The ampoule lid 220 in some embodiments is configured to be attached to the ampoule base 210 by any suitable connections including, but not limited to, welding, friction fit, bolts between a flange (not shown) on each of the ampoule lid 220 and the ampoule base 210.

The ampoule lid 220 has an outside surface 222 and an inside surface 224. When connected to the top end 215 of the sidewall 214, the ampoule lid 220 encloses the interior volume 216 of the ampoule 201.

An inlet conduit 240 is in fluid communication with the interior volume 216 of the ampoule 201. The inlet conduit 240 has an outside end 241 located on the outside of the ampoule 201. Stated differently, the outside end 241 is on the side of the ampoule lid 220 with the outside surface 222. The inlet conduit 240 has an inside end 242 located within the interior volume 216 of the ampoule 201. In an embodiment in which there is no ampoule base 210, the inside end 242 of the inlet conduit 240 is on the side of the ampoule lid 220 with the inside surface 224.

The inside end 242 of the inlet conduit 240 in some embodiments is configured to be flush with the inside surface 224 of the ampoule lid 220. In the embodiments shown in FIGS. 2A-C, the inside end 242 of the inlet conduit 240 extends a distance from the inside surface 224 of the ampoule lid 220. In some embodiments, the distance that the inlet conduit 240 extends from the inside surface 224 of the ampoule lid 220 is sufficient to bring the inside end 242 of the inlet conduit 240 to a distance in the range of about 10 mm to about 100 mm from the bottom 212 of the ampoule base 210. In some embodiments, the inside end 242 of the inlet conduit is submerged in the liquid precursor 211 during processing of a substrate in which precursor vapor is delivered to a processing chamber 283 during a film formation process. In other embodiments, the inside end 242 of the inlet conduit is not submerged in the liquid precursor 211 during processing of a substrate in which precursor vapor is delivered to a processing chamber 283 during a film formation process. In other words, the inside end 242 of the inlet conduit is in the headspace 213 during a film formation process.

In some embodiments, an inlet disconnect 245 is located at the outside end 241 of the inlet conduit 240. The inlet disconnect 245 can be any component that allows the inlet conduit 240 to be connected to and disconnected to another component, for example, a gas supply 279, which may contain a carrier gas 203 such as air or nitrogen. For example, the inlet disconnect 245 can be a coupling with screw threads to allow the inlet disconnect 245 to be screwed into a receiving nut (not shown). The inlet disconnect 245 is in fluid communication with the inlet conduit 240 so that a fluid such as a gas from the gas supply can flow through the outside end 241 of the inlet conduit 240. While not shown, the apparatus can utilized a mass flow controller or a volume flow controller to regulate the flow of the gas from the gas supply 279 to the inlet conduit 240.

In some embodiments, the inside end 242 of the inlet conduit 240 has a component to redirect or diffuse the flow of carrier gas through the inlet conduit 240. In some embodiments, a sparger 247 is positioned on the inside end 242 of the inlet conduit 240. The sparger 247 is in fluid communication with the inlet conduit 240 to allow a gas flowing through the inlet conduit 240 to pass through the sparger 247 to bubble through the liquid precursor 211.

In some embodiments, the inside end 242 of the inlet conduit 240 is above the liquid level surface 211a of liquid precursor 211. In one or more embodiments, the inside end 242 of the inlet conduit 240 and the inside end 252 of the outlet conduit 250 do not contact the liquid precursor 211. In an embodiment of this sort, a vapor of the precursor in the headspace 213 above the liquid precursor 211 is carried through the outlet conduit 250 as carrier gas exiting the ampoule mixed with the vapor of the precursor 205, which is delivered to the processing chamber 283.

An outlet conduit 250 is in fluid communication with the interior volume 216 of the ampoule 201. The outlet conduit 250 has an outside end 251 located on the outside of the ampoule 201. In an embodiment in which there is no ampoule base 210, the outside end 251 is located on the outside surface 222 side of the ampoule lid 220. The outlet conduit 250 has an inside end 252 which, in the embodiments shown in FIGS. 2A-C, can be located within the interior volume 216 of the ampoule 201. In an embodiment in which there is no ampoule base 210, the inside end 252 of the outlet conduit is on the inside surface 224 side of the ampoule lid 220.

In one or more embodiments, the inside end 252 of the outlet conduit 250 can be flush with the inside surface 224 of the ampoule lid 220. In the embodiments shown in FIGS. 2A-C, the inside end 252 extends a distance from the inside surface 224. Stated differently, the outlet conduit 250 extends a distance from the inside surface 224 of the ampoule lid 220 so that the inside end 252 is a distance within the interior volume 216 of the ampoule 201. The distance that the inside end 252 extends from the inside surface 224 can vary in the range of about flush with the inside surface 224 to 50 mm. In some embodiments, the inside end 252 extends from the inside surface 224 by an amount less than or equal to about 40 mm, 30 mm, 20 mm or 10 mm. In some embodiments, the inside end 252 of the outlet conduit 250 is at least about 1 mm from the inside surface 224 so that the inside end 252 is not flush with the inside surface 224. In some embodiments, the inside end 252 extends from the inside surface 224 by an amount in the range of about 1 mm to about 40 mm, or about 2 mm to about 35 mm, or about 3 mm to about 30 mm, or about 4 mm to about 25 mm, or about 5 mm to about 20 mm.

In an embodiment, the inside end 252 of the inlet conduit 240 does not extend far enough from the inside surface 224 of the ampoule lid 220 to contact the liquid precursor 211. In one or more embodiments, the inside end 252 of the outlet conduit 250 sticks out from the inside surface 224 of the ampoule lid 220 a small amount toward the liquid precursor 211. The edge of the inside end 252 may reduce condensed liquid or splashed liquid from entering the outlet conduit 250. The inside end 252 of the outlet conduit 250 does not extend into the interior volume 216 far enough to reduce the amount of precursor being delivered.

In some embodiments, the outlet conduit 250 includes an outlet disconnect 255 at an outside end 251. The outlet disconnect 255 is in fluid communication with the outlet conduit 250 so that a fluid such as a vapor of the precursor entrained in the carrier gas flows from the ampoule 201, through the outlet conduit 250, and through the outlet disconnect 255. The outlet disconnect 255 can be any component that allows the outlet conduit 250 to be connected to and disconnected from. For example, the outlet disconnect 255 can be a coupling with screw threads to allow the outlet disconnect 255 to be screwed into a receiving nut (not shown). The outlet disconnect 255 can be the same style or size as the inlet disconnect 245. In some embodiments, the inlet disconnect 245 and the outlet disconnect 255 are different sizes so that the inlet conduit 240 and outlet conduit 250 can be easily distinguished. In the embodiments shown, the outlet disconnect 255 is connected to a processing chamber 283 such as a film forming chamber into which precursor vapor entrained in a carrier gas is delivered for film deposition process. The processing chamber in the form a film forming chamber can be an atomic layer deposition chamber, a chemical vapor deposition chamber or a plasma enhanced chemical vapor deposition chamber.

Some embodiments include a splash guard (not shown). The splash guard can be connected to the inside surface 224 of the ampoule lid 220 or to the sidewall 214 of the ampoule base 210. The inside end 252 of the outlet conduit 250 can extend into the headspace 213 above the liquid precursor 211 by an amount to serve as a splash guard. The use of both a splash guard (not shown) and the inside end 252 of the outlet conduit 250 extending into the headspace 213 above the liquid precursor 211 has been found to reduce precursor entrapment and liquid flush.

The valve cluster 232 includes a first inlet valve 261 in fluid communication with the inlet conduit 240. The first inlet valve 261 is located upstream of the ampoule 201 or ampoule lid 220 adjacent to the outside surface 222. The first inlet valve 261 can be placed as close to the outside surface 222 of the ampoule lid 120 as possible or can be spaced a distance from the outside surface 222.

The first inlet valve 261 can be any suitable valve that allows fluid communication between the upstream side of the valve and the downstream side of the valve. The first inlet valve 261 of some embodiments is a three-way valve that allows a flow of gas to pass from the upstream side of the valve to one or two downstream legs. For example, the first inlet valve 261 in the embodiments shown in FIGS. 2A-C is a three-way valve that allows the flow of gas to pass through the first inlet valve 261 to flow into the interior volume 216 of the ampoule 201 or to flow into the bypass conduit 280.

The first inlet valve 261 can be a manual valve which is operated by hand or can be a pneumatic valve that can be controlled electronically. In some embodiments, the first inlet valve 261 is a pneumatic valve.

A second inlet valve 266 in fluid communication with the inlet conduit 240. The second inlet valve 266 is located upstream of the first inlet valve 261. The second inlet valve 266 is spaced from the first inlet valve 261 along a length of the inlet conduit 240. The space between the first inlet valve 261 and the second inlet valve 266 can be any space and is not limited to short distances, e.g. less than 50 mm.

The second inlet valve 266 can be a manual valve which is operated by hand or a pneumatic valve which can be electronically controlled. In some embodiments, the second inlet valve 266 is a manual valve and the first inlet valve 261 is a pneumatic valve.

A first outlet valve 271 is in fluid communication with the outlet conduit 250. The first outlet valve 271 is located downstream of the ampoule lid 220. The first outlet valve 271 is located upstream of the ampoule lid 220 adjacent to the outside surface 222 of the ampoule lid 220. The first outlet valve 271 can be placed as close to the outside surface 222 of the ampoule lid 220 as possible or can be spaced a distance from the outside surface 222.

The first outlet valve 271 can be any suitable valve that allows fluid communication between the upstream side of the valve (i.e., nearer the ampoule) and the downstream side (i.e., further from the ampoule) of the first outlet valve 271. The first outlet valve 271 of some embodiments is a three-way valve that allows a flow of fluid to pass from the upstream side of the valve from one or two legs to the downstream side of the valve. For example, the first outlet valve 271 in the embodiments shown in FIGS. 2A-C is a three-way valve that allows the flow of fluid to pass through the first outlet valve 271 from the interior volume 216 of the ampoule 201 or from the bypass conduit 280, or from both.

The first outlet valve 271 can be a manual valve which is operated by hand or can be a pneumatic valve that can be controlled electronically. In some embodiments, the first outlet valve 271 is a pneumatic valve.

A second outlet valve 276 in fluid communication with the outlet conduit 250. The second outlet valve 276 is located downstream of the first outlet valve 271. The second outlet valve 276 is spaced from the first outlet valve 271 along a length of the outlet conduit 250. The space between the first outlet valve 271 and the second outlet valve 276 can be any space and is not limited to short distances such at 50 mm.

The second outlet valve 276 can be a manual valve which is operated by hand or a pneumatic valve which can be electronically controlled. In some embodiments, the second outlet valve 276 is a manual valve and the first outlet valve 271 is a pneumatic valve.

A bypass conduit 280 is coupled to and in fluid communication with the inlet conduit 240 and the outlet conduit 250. In the embodiments shown, the bypass conduit 280 is coupled to the first inlet valve 261 and the first outlet valve 271. In the flow path, the first inlet valve 261 can be a three-way valve that allows the flow of fluid to pass through the first inlet valve 261 from the upstream side (i.e., further from the interior volume 216) to the interior volume 216 or to the bypass conduit 280, or a combination of both. The fluid flowing through the bypass conduit 280 can pass through the first outlet valve 271 which is a three-way valve that allows fluid from the bypass conduit 280, the interior volume 216 of the ampoule 201, or both to pass through.

In some embodiments, the bypass conduit 280 includes a bypass valve 281 in fluid communication with the bypass conduit 280. The bypass valve 281 can be a manual valve which is operated by hand or a pneumatic valve which can be electronically controlled. In some embodiments, the bypass valve 281 is a pneumatic valve. In one or more embodiments, the first inlet valve 261, the first outlet valve 271 and the bypass valve 281 are pneumatic valves.

In use, the gas supply 279 supplies a carrier gas (e.g., argon, nitrogen, or air), which flows into the inlet conduit 240 through the outside end 241. The gas passes through the second inlet valve 266 from an upstream side of the valve to the downstream side of the valve. The gas passes through the first inlet valve 261 from an upstream side of the valve to the downstream side of the valve. The gas then passes into the interior volume 216 of the ampoule through the sparger 247. In the interior volume 216, the gas disturbs the liquid precursor 211 and carries precursor molecules to inside end 252 of the outlet conduit 250. In one or more embodiments, the precursor molecules are in vapor form. The carrier gas including the precursor flows through the first outlet valve 271 and the second outlet valve 276 toward, for example, the processing chamber 283. Once the process has been completed, the first inlet valve 261 and first outlet valve 271 can be closed, or diverted to allow flow through the bypass conduit 280. The bypass valve 281 can be opened allowing the carrier gas, or purge gas, to flow through the second inlet valve 266 and the first inlet valve 261 before passing through the bypass valve 281 and bypass conduit 280. The purge gas then flows through the first outlet valve 271 and the second outlet valve 276 of the outlet conduit 250 removing all residue of the precursor that may remain in the outlet conduit 250.

In the embodiments shown in FIGS. 2A-C, there is needle valve 265 connected to the outlet conduit 250. It will be understood that the needle valve 265 could be connected to the outlet conduit at any point along the length between the ampoule lid 220 and the outside end. Thus, the location of the needle valve 265 is not limited to the locations shown in FIGS. 2A-C. The needle valve 265 could be upstream or before the first outlet valve 271 or downstream from the second outlet valve 276

The gas pressure sensor 225 can be in a variety of locations with respect to the gas delivery system 230. In FIG. 2A, a gas pressure sensor 225 is connected to the inlet conduit downstream from the gas supply and upstream from the second inlet valve. In FIG. 2B, the gas pressure sensor 225 is connected to the bypass conduit 280 and between the first inlet valve 261 and the bypass valve 281, however, the gas pressure sensor 225 may also be located between the bypass valve 281 and the first outlet valve 271. FIG. 2C shows a configuration in which the gas pressure sensor 225 is connected to the outlet conduit 250 downstream from the second outlet valve 276 and between the second outlet valve 276 and the processing chamber 283.

Referring back to FIGS. 2A-C, the apparatus 200 according to one or more embodiments comprises a first controller 291. The first controller 291 according to one or more embodiments comprises a first processor 293, a first memory 295 coupled to the processor, input/output devices coupled to the first processor 293, and support circuits to provide communication between the different components of the system or apparatus, operation of the valve cluster 232 and flow of gas to the processing chamber 283. The first controller 291 is in communication with the gas pressure sensor 225 and the needle valve 265 to regulate the pressure of the gas in the gas delivery system 230. In some embodiments, the first controller 291 is in communication with the gas pressure sensor 225 and the needle valve 265, and the first controller 291 is configured to send a signal to adjust the needle valve 265 to change the gas pressure in the gas delivery system 230. In embodiments in which the needle valve 265 is a manually controlled needle valve, the signal can be an alert to indicate that the needle valve 265 requires adjustment to regulate or change the gas pressure in the gas delivery system. In specific embodiments, the first controller 291 adjusts opening and closing of the needle valve 265 in embodiments in which the needle valve 265 comprises a motor controlled valve. In such embodiments, the first controller 291 is configured to automatically operate the needle valve 265 to regulate or change the gas pressure in the gas delivery system 230, for example to a predetermined gas pressure value.

Additionally, the valve cluster 232 may be enclosed by a first heated enclosure 296 to heat the valve cluster 232 during a film forming operation. The first controller 291, the first processor 293 and the first memory 295 may also control heating and cooling of the first heated enclosure 296. Processes to operate the system or apparatus 200 may generally be stored in the memory as a software routine that, when executed by the processor, causes the system or apparatus 200 to perform methods described in the present disclosure. The software routine may also be stored and/or executed by a second processor (not shown) that is remotely located from the hardware being controlled by the processor. Some or all of the methods of the present disclosure may also be performed by hardware. As such, the methods described in this disclosure are implemented in software and executed using a computer system, by hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

The apparatus 200 according to one or more embodiments can comprise a second controller 290. The second controller 290 according to one or more embodiments comprises a second processor 292, a second memory 294 coupled to the processor, input/output devices coupled to the second processor 292, and support circuits to provide communication between the different components of the system or apparatus, operation of a second heated enclosure 298 surrounding the ampoule 201 and flow of gas from the gas supply 279 to the ampoule 201 and to the processing chamber 283. The second controller 290, the second processor 292 and the second memory 294 may also control heating and cooling of the second heated enclosure 298. Processes to operate the system or apparatus 200 may generally be stored in the memory as a software routine that, when executed by the processor, causes the system or apparatus 200 to perform methods described in the present disclosure. The software routine may also be stored and/or executed by a second processor (not shown) that is remotely located from the hardware being controlled by the processor. Some or all of the methods of the present disclosure may also be performed y hardware. As such, the methods described in this disclosure are implemented in software and executed using a computer system, by hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

The first memory 295 and the second memory 294 of one or more embodiments includes one or more of transitory memory (e.g., random access memory) and non-transitory memory (e.g., storage) and the memory of the processor may be one or more of readily available memory such as random access memory (RAM), read-only memory (ROM), floppy disk, hard disk, or any other form of digital storage, local or remote. The memory can retain an instruction set that is operable by the processor to control parameters and components of the system. The support circuits are coupled to the processor for supporting the processor in a conventional manner. Circuits may include, for example, cache, power supplies, clock circuits, input/output circuitry, subsystems, and the like.

In one or more embodiments, the first controller 291 and the second controller 290 execute instructions deliver precursor from the ampoule 201 to the processing chamber 283. In some embodiments, the first controller 291 controls operation of the motor controlled linear actuator such as the piezoelectric linear controlled actuator to precisely regulate concentration of the precursor flowed from the ampoule 201 to the process chamber 283.

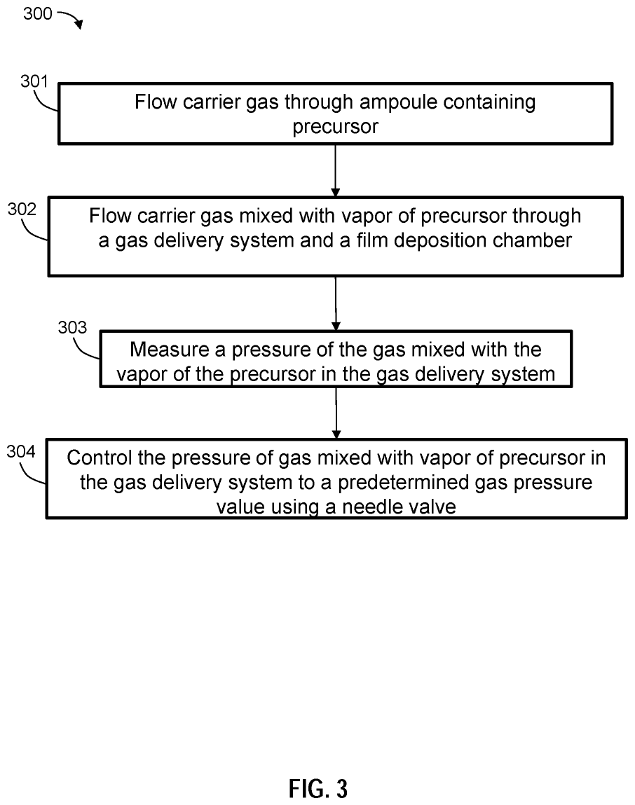

Embodiments of the disclosure further pertain to method of delivering a precursor to a processing chamber. Referring now to FIG. 3, in one or more embodiments, a method 300 comprises of controlling flow of gas in a film deposition chamber. In the embodiment shown, the method includes at 301 flowing a carrier gas through an ampoule having an interior volume containing a precursor, the carrier gas exiting the ampoule mixed with a vapor of the precursor. At 302, the method includes flowing the carrier gas mixed with the vapor of the precursor through a gas delivery system and to the film deposition chamber. At 303, the method includes measuring a pressure of the gas mixed with the vapor of the precursor in the gas delivery system. At 304, the method includes controlling the pressure of the gas mixed with the vapor of the precursor in the gas delivery system to a predetermined gas pressure value using a needle valve in communication with a gas pressure sensor.

In some method embodiments, the pressure of the gas mixed with the precursor vapor is controlled by a controller in communication with a gas pressure sensor and the needle valve, and the method further comprises the controller sending a signal to adjust the needle valve to change the gas pressure in the gas delivery system. In some method embodiments, the gas delivery system includes a valve cluster connected to the outside surface of the ampoule, the valve cluster including an inlet conduit connected to the ampoule and configured to allow gas to flow into the ampoule, an outlet conduit connected to the ampoule and configured to allow gas to flow out of the ampoule, a first inlet valve connected to the inlet conduit, and a first outlet valve connected to the outlet conduit.

In some method embodiments, the needle valve comprises a manual valve including a Vernier handle. In some method embodiments, the needle valve comprises a motor controlled needle valve in communication with the controller. In such embodiments, the method may comprise the controller adjusting the needle valve to regulate or change the pressure of the gas in the gas delivery system to a predetermined gas pressure value. In one or more embodiments, the motor controlled valve comprises a piezoelectric controlled linear actuator.

In one or more embodiments of the method or apparatus described herein, precursor comprises a compound that is susceptible to formation of particulate contamination in the gas delivery system. It was determined that certain precursors comprise a compound that is reactive with moisture or oxygen and forms particulate in the gas delivery system. This particulate formed in the gas delivery system form particulate contamination that blocks certain types of flow restrictive devices that are used to adjust the pressure in the gas delivery system. It was determined that a needle valve did not encounter problems experienced with other types of flow restrictive devices. For example, it was found that using a porous metal flow restrictor resulted in particles being formed during a film formation process, and the amount of particle increased during duration of the process. For example, in an atomic layer deposition process to form silicon nitride (SiN) process using a diiodoSilane (DIS) precursor, a porous metal flow restrictor generated an unacceptably high amount of particulate in the gas delivery system. In a direct liquid injection process, liquid is injected into a chamber and evaporated at elevated temperature. The high temperature caused the decomposition of DIS resulting in device clogging after less than 2 kg of chemical was used. Furthermore, VCR orifice gasket restrictors can have variability in the pin hole size in flow restrictor, which can result in 20% variation of conductance from restrictor to restrictor. The needle valve provides the ability to adjust and control precise amount of precursor delivered to a processing chamber during a film formation process. The needle valve provided improved process control and process optimization. Use of a needle valve ensures lower particle counts in the processing chamber. The method and apparatus provide reliable delivery liquid or solid precursors that are thermally unstable at high temperature and/or highly sensitive and/or reactive with moisture or oxygen. In one or more embodiments of the method or apparatus, the precursor comprises a compound selected from the group consisting of a organometallic compound, a metal halide such as SiCl4, SiBr4, Sil4; trimethyl aluminum, tetrakis(ethylmethylamido)hafnium (IV), and silicon compounds such as silicon-containing silanes, e.g., diiodosilane, dichlorosilane, and dibromosilane, and other organosilanes.

One or more embodiments provide apparatus and methods comprising a gas sensor and a needle valve that are utilized to regulate or change the pressure in a gas delivery system of a processing chamber. The apparatus and methods according to embodiments provide reduced particulate contamination in the gas delivery system of gas mixed with precursor vapors delivered to processing chambers compared to apparatus and methods that do not utilize other types of flow restrictive devices to regulate the gas pressure in the gas delivery system. Embodiments of the disclosure enable the control of the exact amount of chemical vapor delivered to the processing chamber. Such control provides repeatable run to run film formation processes and the ability to match precise formation of films in different chambers, especially for processes that are very sensitive to the amount of precursors delivered during film formation processes, for examples an atomic layer deposition process using diiodosilane precursor. The needle valve provides the ability to have chamber set-up matching and to provide will equal flow conductance between chambers.

While the foregoing is directed to embodiments of the present invention, other and further embodiments of the disclosure may be devised without departing from the basic scope thereof, and the scope thereof is determined by the claims that follow.

What is claimed is:

1. A method of controlling flow of gas in a film deposition chamber, the method comprising:
flowing a carrier gas through an ampoule having an interior volume containing a precursor that is thermally unstable or reactive with oxygen and moisture, the carrier gas exiting the ampoule mixed with a vapor of the precursor;
flowing the carrier gas mixed with the vapor of the precursor through a gas delivery system and to the film deposition chamber;
measuring a pressure of the gas mixed with the vapor of the precursor in the gas delivery system; and
controlling the pressure of the gas mixed with the vapor of the precursor in the gas delivery system to a predetermined gas pressure value using a needle valve in communication with a gas pressure sensor, wherein controlling the pressure of the gas mixed with the vapor of the precursor that is thermally unstable or reactive with oxygen and moisture reduces the formation of particulate contaminants in the gas delivery system.

2. The method of claim 1, wherein the pressure of the gas mixed with the precursor vapor is controlled by a controller in communication with a gas pressure sensor and the needle valve, and the method further comprises the controller sending a signal to adjust the needle valve to change the gas pressure in the gas delivery system.

3. The method of claim 2, wherein the gas delivery system includes a valve cluster connected to the outside surface of the ampoule, the valve cluster including an inlet conduit connected to the ampoule and configured to allow gas to flow into the ampoule, an outlet conduit connected to the ampoule and configured to allow gas to flow out of the ampoule, a first inlet valve connected to the inlet conduit, and a first outlet valve connected to the outlet conduit.

4. The method of claim 2, wherein the needle valve comprises a manual valve including a Vernier handle.

5. The method of claim 4, the needle valve comprising a motor controlled needle valve in communication with the controller.

6. The method of claim 5, wherein the motor controlled needle valve comprises a piezoelectric controlled linear actuator.

7. The method of claim 6, wherein the precursor comprises a compound that is susceptible to formation of particulate contamination in the gas delivery system.

8. The method of claim 7, wherein the precursor comprises a compound that is reactive with moisture and forms particulate.

9. The method of claim 8, wherein the precursor comprises a compound selected from the group consisting of an organometallic compound, a metal halide; trimethyl aluminum, tetrakis(ethylmethylamido)hafnium (IV), and silicon-containing silanes, diiodosilane, dichlorosilane, dibromosilane, SiCl₄, SiBr₄, and Silo.

10. The method of claim 8, wherein the precursor comprises diiodosilane.

11. The method of claim 8, wherein the precursor comprises tetrakis(ethylmethylamido)hafnium (IV).

12. The method of claim 3, further comprising a first heated enclosure enclosing the needle valve.

13. The method of claim 12, further comprising controlling heating and cooling of the first heated enclosure with a first controller.

14. The method of claim 13, wherein the first heated enclosure encloses the valve cluster.

15. The method of claim 13, further comprising a second heated enclosure surrounding the ampoule.

16. The method of claim 15, further comprising controlling heating and cooling of the second heated enclosure with a second controller.
